(19) United States
(12) Patent Application Publication
(10) Pub. No.: US 2013/0340802 A1
(43) Pub. Date: Dec. 26, 2013

(54) THERMOELECTRIC GENERATOR FOR USE WITH INTEGRATED FUNCTIONALITY

(71) Applicant: Gentherm Incorporated, Northville, MI (US)

(72) Inventors: Vladimir Jovovic, Pasadena, CA (US); Douglas T. Crane, Altadena, CA (US); Dmitri Kossakovski, South Pasadena, CA (US)

(21) Appl. No.: 13/926,791

(22) Filed: Jun. 25, 2013

Related U.S. Application Data
(60) Provisional application No. 61/664,621, filed on Jun. 26, 2012.

(51) Int. Cl. H01L 35/30

(52) U.S. Cl. CPC H01L 35/30
USPC 136/201; 136/205; 123/2

(57) ABSTRACT

A thermoelectric system includes at least one thermoelectric generator which includes at least one cold-side heat exchanger, at least one hot-side heat exchanger, and a plurality of thermoelectric elements in thermal communication with the at least one cold-side heat exchanger and in thermal communication with the at least one hot-side heat exchanger. The system further includes a combustible fluid, wherein the at least one cold-side heat exchanger is configured to transfer heat to the combustible fluid.

### CROSS-REFERENCE TO RELATED APPLICATIONS

The application claims the benefit of priority to U.S. Provisional Appl. No. 61/664,621, filed Jun. 26, 2012 and incorporated in its entirety by reference herein.

### BACKGROUND

1. Field

The present application relates generally to thermoelectric power generation systems used in conjunction with oil or gas pipelines or reservoirs.

2. Description of the Related Art

Thermoelectric (TE) modules have been manufactured for specific niche power generation applications. These modules include TE materials connected together with electrodes and sandwiched between two ceramic substrates. These modules have been used as building blocks for thermoelectric devices and systems. They have often been connected to heat exchangers, sandwiched between hot and cold (or waste and main) sides.

### SUMMARY

Certain embodiments described herein provide a thermoelectric system comprising at least one thermoelectric generator which comprises at least one cold-side heat exchanger, at least one hot-side heat exchanger, and a plurality of thermoelectric elements in thermal communication with the at least one cold-side heat exchanger and in thermal communication with the at least one hot-side heat exchanger. The system further comprises a combustible fluid, wherein the at least one cold-side heat exchanger is configured to transfer heat to the combustible fluid.

Certain embodiments described herein provide a system comprising an engine and at least one thermoelectric generator. The at least one thermoelectric generator comprises at least one cold-side heat exchanger, at least one hot-side heat exchanger, and a plurality of thermoelectric elements in thermal communication with the at least one cold-side heat exchanger and in thermal communication with the at least one hot-side heat exchanger. The at least one thermoelectric generator further comprises an engine lubricant, wherein the at least one cold-side heat exchanger is configured to transfer heat to the engine lubricant.

Certain embodiments described herein provide a method of heating a combustible fluid. The method comprises generating electricity by providing heat to at least one thermoelectric generator comprising at least one cold-side heat exchanger, at least one hot-side heat exchanger, and a plurality of thermoelectric elements in thermal communication with the at least one cold-side heat exchanger and in thermal communication with the at least one hot-side heat exchanger. The method further comprises transferring heat from the at least one cold-side heat exchanger to the combustible fluid.

Certain embodiments described herein provide a method of heating an engine lubricant. The method comprises generating electricity by providing heat to at least one thermoelectric generator comprising at least one cold-side heat exchanger, at least one hot-side heat exchanger, and a plurality of thermoelectric elements in thermal communication with the at least one cold-side heat exchanger and in thermal communication with the at least one hot-side heat exchanger. The method further comprises transferring heat from the at least one cold-side heat exchanger to an engine lubricant.

Certain embodiments described herein provide a thermoelectric system comprising at least one thermoelectric generator and a burner. The at least one thermoelectric generator comprises at least one cold-side heat exchanger, at least one hot-side heat exchanger, and a plurality of thermoelectric elements in thermal communication with the at least one cold-side heat exchanger and in thermal communication with the at least one hot-side heat exchanger. The at least one thermoelectric generator further comprises a combustible fluid, wherein the at least one cold-side heat exchanger is configured to transfer heat to a portion of the combustible fluid. The burner is configured to combust the portion of the combustible fluid and to provide heat to the at least one hot-side heat exchanger.

Certain embodiments described herein provide a method of generating electricity by combusting a combustible fluid. The method comprises generating electricity using at least one thermoelectric generator comprising at least one cold-side heat exchanger, at least one hot-side heat exchanger, and a plurality of thermoelectric elements in thermal communication with the at least one cold-side heat exchanger and in thermal communication with the at least one hot-side heat exchanger. The method further comprises transferring heat from the at least one cold-side heat exchanger to the combustible fluid to preheat the combustible fluid. The method further comprises combusting the preheated combustible fluid to provide heat to the at least one hot-side heat exchanger.

### BRIEF DESCRIPTION OF THE DRAWINGS

Various configurations are depicted in the accompanying drawings for illustrative purposes, and should in no way be interpreted as limiting the scope of the thermoelectric assemblies or systems described herein. In addition, various features of different disclosed configurations can be combined with one another to form additional configurations, which are part of this disclosure. Any feature or structure can be removed, altered, or omitted. Throughout the drawings, reference numbers may be reused to indicate correspondence between reference elements.

FIG. 1 schematically illustrates a conventional passively-cooled TEG system operating on a petroleum pipeline.

FIGS. 2A and 2B schematically illustrate example thermoelectric systems in accordance with certain embodiments described herein.

FIGS. 3A-3D schematically illustrate example thermoelectric systems flowing a fluid through a cold-side heat exchanger in accordance with certain embodiments described herein.

FIGS. 4A and 4B schematically illustrate example TE systems utilizing a secondary cooling loop and a pipeline in accordance with certain embodiments described herein.

FIGS. 5A and 5B schematically illustrate example TE systems transmitting heat to the container and utilizing preheating of fluid from the container prior to being combusted by the burner in accordance with certain embodiments described herein.

FIGS. 6A and 6B schematically illustrate example TE systems utilizing preheating of fluid from the container prior to being combusted by the burner in accordance with certain embodiments described herein.

FIG. 7 schematically illustrates an example thermoelectric system comprising a TEG and a combustor in accordance with certain embodiments described herein.

FIGS. 8A and 8B schematically illustrate example thermoelectric systems that are configured to use an energy transmission element to transfer heat from the cold-side heat exchanger to the fluid in a pipeline in accordance with certain embodiments described herein.

FIGS. 9A and 9B schematically illustrate example thermoelectric systems in which fluid from a reservoir is directly circulated through at least one TEG in accordance with certain embodiments described herein.

FIGS. 10A and 10B schematically illustrate example TE systems utilizing a secondary cooling loop and a reservoir in accordance with certain embodiments described herein.

FIGS. 11A and 11B schematically illustrate example thermoelectric systems that are configured to use an energy transmission element to transfer heat from the cold-side heat exchanger to the fluid in a reservoir in accordance with certain embodiments described herein.

FIG. 12 schematically illustrates an example processing system for crude oil in accordance with certain embodiments described herein.

FIG. 13 is a flow diagram of an example method for heating a fluid (e.g., combustible fluid, petroleum, crude oil) in accordance with certain embodiments described herein.

FIG. 14 is a flow diagram of an example method for generating electricity by combusting a combustible fluid in accordance with certain embodiments described herein.

### DETAILED DESCRIPTION

Although certain configurations and examples are disclosed herein, the subject matter extends beyond the examples in the specifically disclosed configurations to other alternative configurations and/or uses, and to modifications and equivalents thereof. Thus, the scope of the claims appended hereto is not limited by any of the particular configurations described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain configurations; however, the order of description should not be construed to imply that these operations are order dependent. Additionally, the structures, systems, and/or devices described herein may be embodied as integrated components or as separate components. For purposes of comparing various configurations, certain aspects and advantages of these configurations are described. Not necessarily all such aspects or advantages are achieved by any particular configuration. Thus, for example, various configurations may be carried out in a manner that achieves or optimizes one advantage or group of advantages as taught herein without necessarily achieving other aspects or advantages as may also be taught or suggested herein.

A thermoelectric system as described herein can be a thermoelectric generator (TEG) which uses the temperature difference between two fluids to produce electrical power via thermoelectric materials. Each of the fluids can be liquid, gas, or a combination of the two, and the two fluids can both be liquid, both be gas, or one can be liquid and the other can be gas. The thermoelectric system can include a single thermoelectric assembly (e.g., a single TE cartridge) or a group of thermoelectric assemblies (e.g., a group of TE cartridges), depending on usage, power output, heating/cooling capacity, coefficient of performance (COP) or voltage. As used herein, the term “TE cartridge” has its broadest reasonable interpretation, including but not limited to, the thermoelectric assemblies and TE cartridges disclosed in currently-pending U.S. patent application Ser. No. 13/489,237 filed Jun. 5, 2012 and incorporated in its entirety by reference herein, and U.S. patent application Ser. No. 13/794,453 filed Mar. 11, 2013 and incorporated in its entirety by reference herein.

As used herein, the terms “shunt” and “heat exchanger” have their broadest reasonable interpretation, including but not limited to a component (e.g., a thermally conductive device or material) that allows heat to flow from one portion of the component to another portion of the component. Shunts can be in thermal communication with one or more thermoelectric materials (e.g., one or more thermoelectric elements) and in thermal communication with one or more heat exchangers of the thermoelectric assembly or system. Shunts described herein can also be electrically conductive and in electrical communication with the one or more thermoelectric materials so as to also allow electrical current to flow from one portion of the shunt to another portion of the shunt (e.g., thereby providing electrical communication between multiple thermoelectric materials or elements). Heat exchangers can be in thermal communication with the one or more shunts and one or more working fluids of the thermoelectric assembly or system. Various configurations of one or more shunts and one or more heat exchangers can be used (e.g., one or more shunts and one or more heat exchangers can be portions of the same unitary element, one or more shunts can be in electrical communication with one or more heat exchangers, one or more shunts can be electrically isolated from one or more heat exchangers, one or more shunts can be in direct thermal communication with the thermoelectric elements, one or more shunts can be in direct thermal communication with the one or more heat exchangers, an intervening material can be positioned between the one or more shunts and the one or more heat exchangers). Furthermore, as used herein, the words “cold,” “hot,” “cooler,” “hotter” and the like are relative terms, and do not signify a particular temperature or temperature range.

As used herein, the term “heat pipe” has its broadest reasonable interpretation, including but not limited to a device that contains a material in a first phase (e.g., a liquid) that is configured (i) to absorb heat at a first position within the device and to change (e.g., evaporate) into a second phase (e.g., gas or vapor) and (ii) to move while in the second phase from the first position to a second position within the device, (iii) to emit heat at the second position and to change back (e.g., condense) into the first phase, and (iv) to return while in the first phase to the first position. As used herein, the term “thermosyphon” has its broadest reasonable interpretation, including but not limited to a device that contains a material (e.g., water) that is configured (i) to absorb heat at a first position within the device, (ii) to move from the first position to a second position within the device, (iii) to emit heat at the second position. For example, the material within the thermosyphon can circulate between the first position and the second position passively (e.g., without being pumped by a mechanical liquid pump) to provide convective heat transfer from the first position to the second position.

As used herein, the term “petroleum” has its broadest reasonable interpretation, including but not limited to hydrocarbons, including crude oil, natural gas liquids, natural gas, and their products. As used herein, the term “combustible” has its broadest reasonable interpretation, including but not limited to capable of igniting and burning. Examples of combustible materials include, but are not limited to, hydrogen, natural gas, gasoline, oil, and other hydrocarbons,

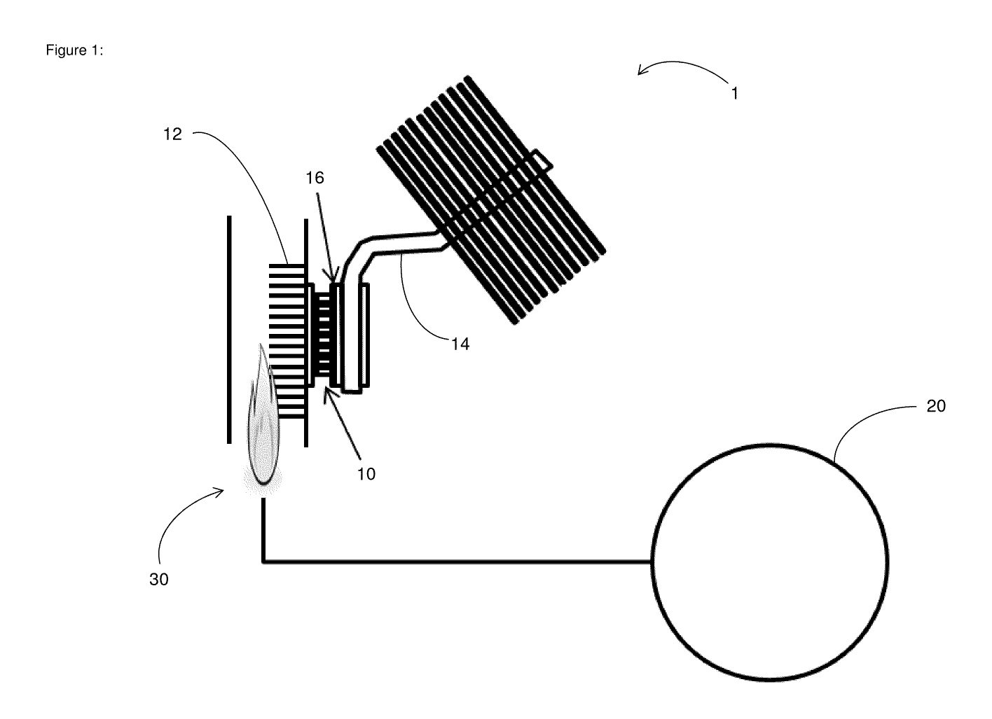

Thermoelectric generators (TEGs) used in remote locations such as, but not limited to, oil and gas pipelines are designed to work with little or no maintenance for extended periods of time. As such, these TEGs are designed to work as passively cooled systems. FIG. 1 schematically illustrates a conventional system 1 comprising a TEG 10 installed on a gas pipeline 20. The system 1 is configured to use gas, either from an external reservoir or syphoned from the pipeline 20 itself, which is burned at the gas burner 30 to provide heat to the TEG 10. The gas burner can be integrated with the TEG 10. A portion of the resulting heat is transferred to the fins of a hot-side heat exchanger 12 of the TEG 10 and is conducted through the TE device (e.g., TE elements or modules) which converts a portion of the heat to electricity. Waste or rejected heat from the TE device is then transferred by at least one energy transmission element 14 (e.g., a heat pipe or thermosyphon) to fins of a cold-side heat exchanger 16 in thermal communication with the environment surrounding the TEG 10. Heat is then passively removed from the cold-side heat exchanger 16 by the environment by means of natural convection and radiation.

Certain embodiments described herein advantageously enable more efficient operation of a TEG integrated with a pipeline or a reservoir containing a fluid (e.g., combustible fluid, petroleum) by transferring heat (e.g., waste heat) from the TEG to the fluid in the pipeline or reservoir. For example, cooling the TEG can be performed using the fluid (e.g., combustible fluid, petroleum) that is moving through the pipeline or is stored in the reservoir. Active cooling or cooling by the fluid can lower the cold-side temperature and can improve the TEG conversion efficiency. In addition, in certain embodiments, the active cooling of the TEG can enable compact, more efficient and higher power density TEG systems.

Certain embodiments described herein advantageously reduce the amount of energy used to transport fluids in pipelines by means of reducing the viscosity of the transported fluid. The transported fluid can be heated and its viscosity reduced by using waste heat from the TEG. For example, certain embodiments can be useful when transporting heavy crude oil which is typically heated to enable pumping. Additional heating of the oil along the pipeline can reduce the line pressure drop, hence, it can reduce the amount of energy otherwise inputted to the oil for pumping. For example, a system can comprise a plurality of TEG stations distributed along the pipeline. The TEG stations can produce electricity used for various purposes, including but not limited to, operating control and monitoring systems, providing cathodic protection of pipeline, operating small pumps and valves, and maintaining elevated fluid temperature to reduce pumping losses.

For example, in certain embodiments, the combined efficiency of TEG/pipeline heater system can be over 90%. Further TEG efficiency improvements can be achieved in certain embodiments by using waste heat from the TEG to preheat the fuel, air, or both used in an integrated burner (e.g., combustor). As a result, certain embodiments described herein can enable more efficient combustion and can reduce greenhouse gas emissions, as compared to systems which do not utilize such preheating.

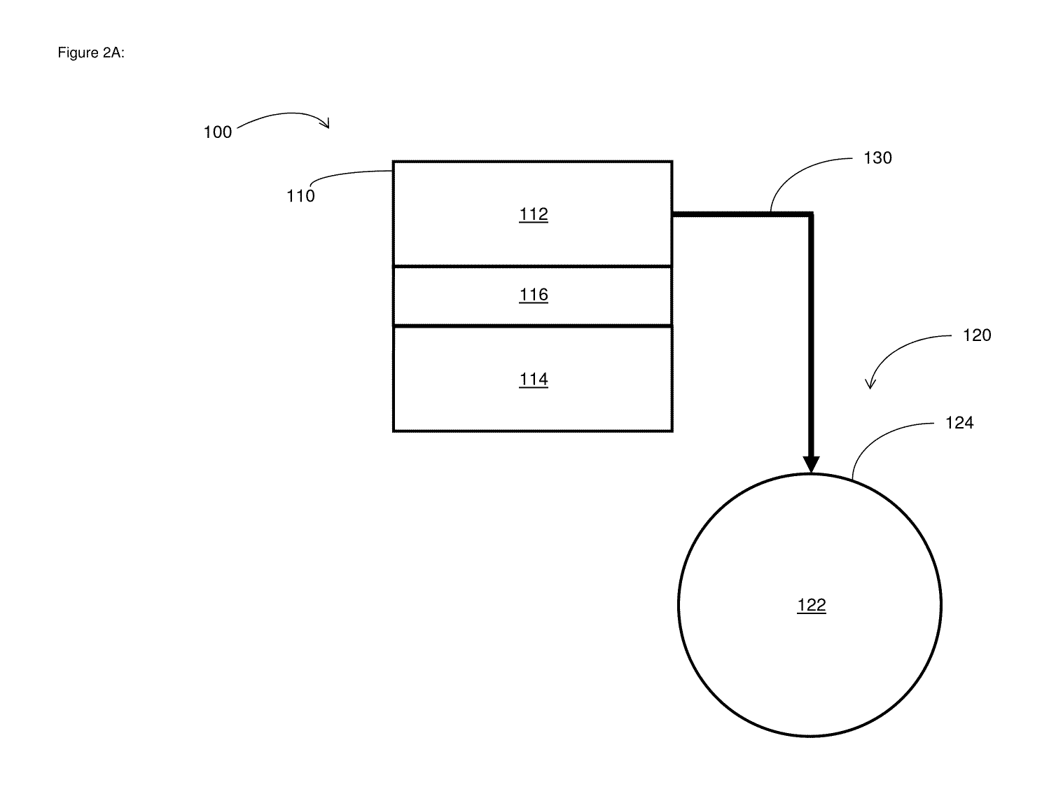

FIGS. 2A and 2B schematically illustrate example thermoelectric systems 100 in accordance with certain embodiments described herein. Each of the thermoelectric systems 100 of FIGS. 2A and 2B comprises at least one thermoelectric generator (TEG) 110 comprising at least one cold-side heat exchanger 112, at least one hot-side heat exchanger 114, and a plurality of thermoelectric elements 116 (e.g., p-n thermoelectric couples in electrical communication with one another by way of electrically conductive shunts) in thermal communication with the at least one cold-side heat exchanger 112 and in thermal communication with the at least one hot-side heat exchanger 114. The thermoelectric system 100 further comprises a fluid 122 (e.g., in a container 120 such as a pipeline 124 through which the fluid 122 flows or a reservoir 126 in which the fluid 122 is held). In the example thermoelectric systems 100 of FIGS. 2A and 2B, the at least one cold-side heat exchanger 112 is configured to transfer heat to the fluid 122. For example, the heat 130 can comprise waste heat from the at least one TEG 110.

In the example thermoelectric system 100 of FIG. 2A, the heat 130 is transferred to the fluid 122 within the container 120. As described more fully below, in certain embodiments, the heat 130 can be transferred to the fluid 122 within the container 120 by flowing a portion of the fluid 122 from the container 120 through the cold-side heat exchanger 112 and returning the heated portion of the fluid 122 to the container 120. In certain other embodiments, the heat 130 can be transferred to the fluid 122 within the container 120 using a secondary cooling loop or an energy transmission element in thermal communication with the cold-side heat exchanger 112 and in thermal communication with the fluid 122 within the container 120, as described more fully below.

In the example thermoelectric system 100 of FIG. 2B, the fluid 122 is combustible (e.g., petroleum) and the heat 130 is transferred to a portion of the fluid 122 that is then transmitted (e.g., flows) to a burner 140 configured to provide heat 142 to the at least one hot-side heat exchanger 114. For example, a portion of the fluid 122 in the container 120 (e.g., petroleum flowing through the pipeline 124) can be directed to flow from the container 120, to flow through the at least one cold-side heat exchanger 112 and then to the burner 140, or the portion of the fluid 122 can be placed in thermal communication with a secondary coolant loop in thermal communication with the cold-side heat exchanger 112. The portion of the fluid 122 receives heat 130 from the at least one TEG 110 (e.g., waste heat that is not converted into electricity) and is therefore preheated prior to being combusted by the burner 140.

The various embodiments described below can provide a thermoelectric system 100 in which a portion of the fluid 122 receives the heat 130 from the at least one cold-side heat exchanger 112. In certain such embodiments, the heated portion of the fluid 122 is within the container 120 (e.g., as schematically illustrated by FIG. 2A). In certain other such embodiments, the heated portion of the fluid 122 is combusted by a burner 140 configured to provide heat 142 to the at least one hot-side heat exchanger 114 with the burner (e.g., as schematically illustrated by FIG. 2B). In still other embodiments, a first portion of the fluid 122 within the container 120 receives the heat 130 from the at least one cold-side heat exchanger 112 and a second portion of the fluid 122 receives the heat 130 from the at least one cold-side heat exchanger 112 and is then combusted by a burner 140.

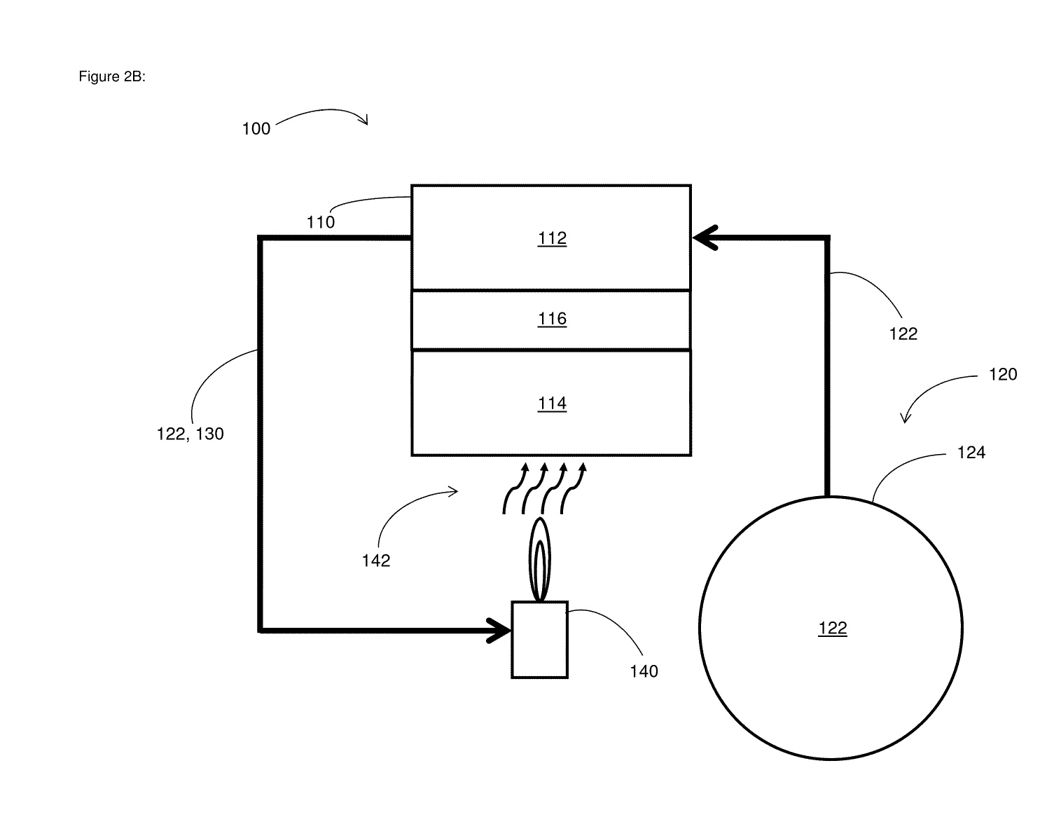

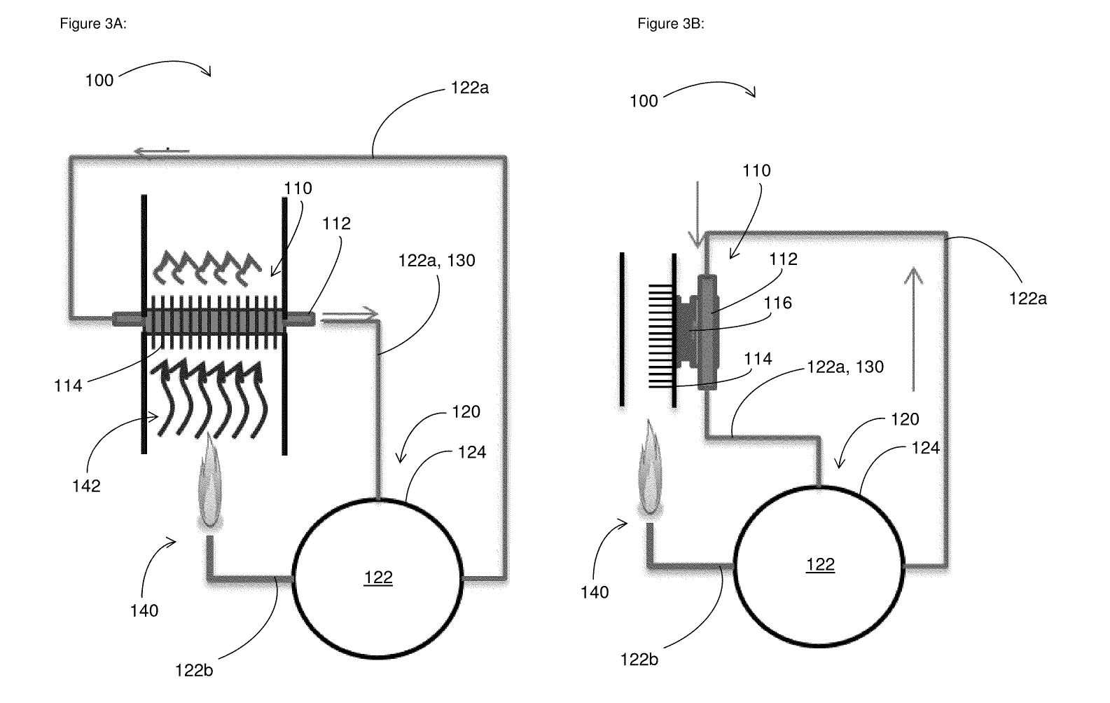

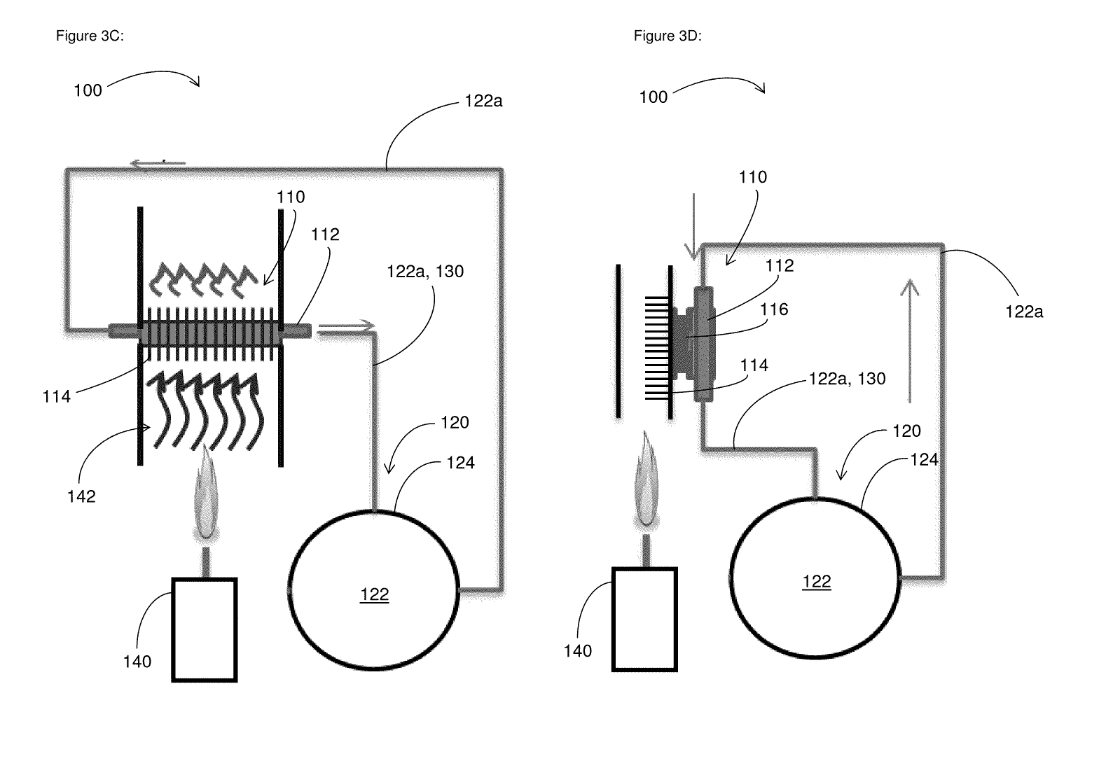

FIGS. 3A-3D schematically illustrate example TE systems 100 in accordance with certain embodiments described herein. The at least one TEG 110 of FIGS. 3A and 3C comprises a TE cartridge comprising a cold-side heat exchanger 112 comprising a generally tubular fluid conduit (e.g., through which fluid 122 from the container 120 flows), a plurality of TE elements and shunts (not shown) which generally encircle and are in thermal communication with the cold-side heat exchanger 112, and a hot-side heat exchanger 114 which generally encircles and is in thermal communication with the plurality of TE elements. For example, as shown schematically in FIGS. 3A and 3C, the hot-side heat exchanger 114 can comprise a plurality of fins in thermal communication with a hot-side working fluid (e.g., flowing in a direction generally perpendicular to a direction of fluid flow through the cold-side heat exchanger 112). Various other configurations of a TE cartridge are compatible for use as the at least one TEG 110 in accordance with certain embodiments described herein. For example, the at least one TEG 110 can comprise one or more of the TE cartridges disclosed in currently-pending U.S. patent application Ser. No. 13/489,237 filed Jun. 5, 2012 and incorporated in its entirety by reference herein, and U.S. patent application Ser. No. 13/794,453 filed Mar. 11, 2013 and incorporated in its entirety by reference herein.

The at least one TEG 110 of FIGS. 3B and 3D comprises a “planar TEG” having a cold-side heat exchanger 112 comprising a fluid conduit (e.g., through which fluid 122 from the container 120 flows), a generally planar array of TE elements 116 having a first side in thermal communication with the cold-side heat exchanger 112 and a second side in thermal communication with the hot-side heat exchanger 114. The hot-side heat exchanger 114 of FIGS. 3B and 3D comprises a plurality of fins in thermal communication with a hot-side working fluid (e.g., flowing in a direction generally parallel to a direction of fluid flow through the cold-side heat exchanger 112). Various other configurations of the at least one TEG 110 are also compatible with certain embodiments described herein.

In FIGS. 3A-3D, fluid 122 (e.g., combustible fluid, petroleum, gas, oil) from the container 120 is directly circulated through the at least one TEG 110. A first portion 122a of the fluid 122 from the container 120 (e.g., flowing through the pipeline 124) is directed to flow from the container 120 through the cold-side heat exchanger 112, and back to the container 120. The first portion 112a of the fluid 122 receives heat 130 from the at least one TEG 110 (e.g., waste heat that is not converted into electricity) and the first portion 122a of the fluid 122 carries the heat 130 into the container 120, where it mixes with the fluid 122 within the container 120 (e.g., the main stream of the fluid 122 flowing through the pipeline 124). In this way, the cold-side heat exchanger 112 of the at least one TEG 110 is configured to transfer heat 130 to the fluid 122.

In FIGS. 3A and 3B, a second portion 122b of the fluid 122 in the container 120 (e.g., flowing through the pipeline 124) is directed to flow from the pipeline 120 to the burner 140. The second portion 122b of the fluid 122 is combusted by the burner 140, which is configured to heat air or another fluid that then flows in thermal communication with the hot-side heat exchanger 114. In this way, the example TE systems 100 of FIGS. 3A and 3B utilize the fluid 122 in the container 120 to cool the at least one TEG 110, and utilize the fluid 122 from the container 120 as fuel for the burner 140. In certain other embodiments, the fluid 122 in the container 120 is used to cool the at least one TEG 110, but is not used to provide fuel to the burner 140. For example, in some instances, the fluid 122 in the container 120 (e.g., being transported in the pipeline 124) may be hard to burn or may not be flammable. As shown in FIGS. 3C and 3D, a separate fuel source can be utilized for operating the burner 140 so as to provide heat 142 to the hot-side heat exchanger 114. Examples of the separate fuel source can include, but are not limited to, a natural gas source and a flue-gas source.

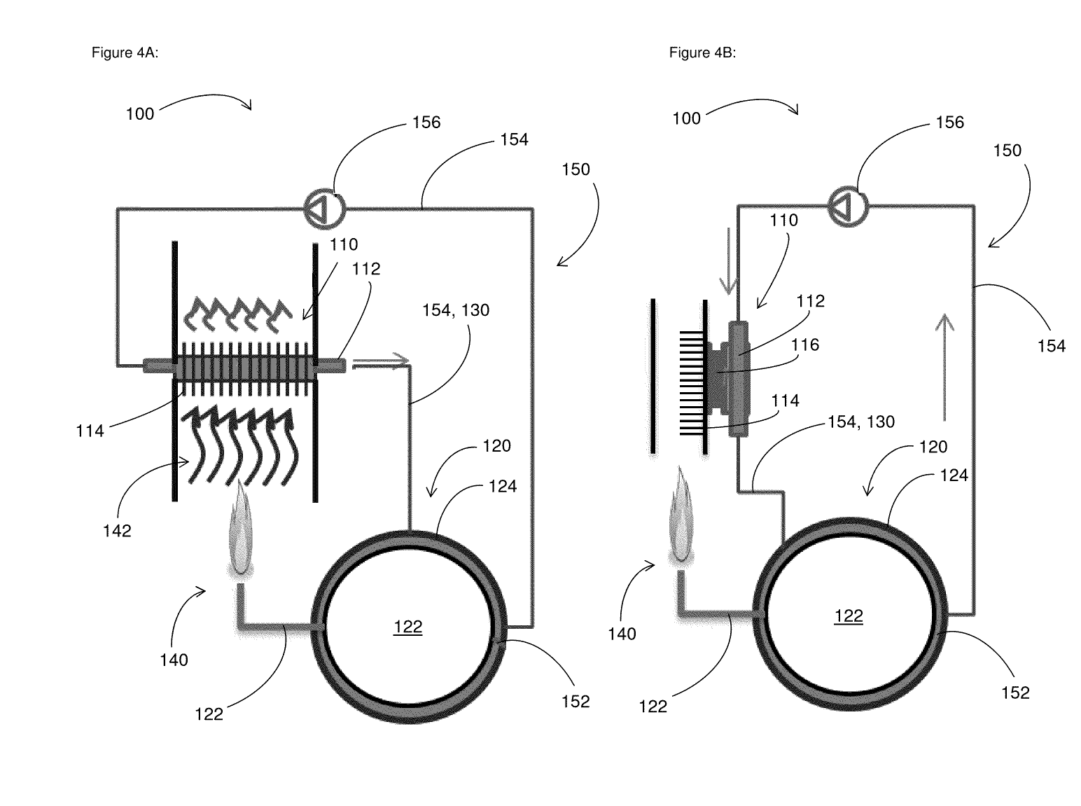

FIGS. 4A and 4B schematically illustrate example TE systems 100 utilizing a secondary cooling loop 150 in accordance with certain embodiments described herein. The at least one TEG 110 of FIG. 4A comprises at least one TE cartridge (e.g., as described above with regard to FIGS. 3A and 3C) and the at least one TEG 110 of FIG. 4B comprises a planar TEG (e.g., as described above with regard to FIGS. 3B and 3D). In FIGS. 4A and 4B, the container 120 (e.g., pipeline 124) comprises a heater jacket 152 in thermal communication with the fluid 122 in the container 120 (e.g., flowing through the pipeline 124). A cold-side working fluid 154 is pumped from the jacket 152 (e.g., via pump 156) to the cold-side heat exchanger 112, where the cold-side working fluid 154 picks up heat 130 from the cold-side heat exchanger 112 (e.g., waste heat) and flows back to the jacket 152 where the cold-side working fluid 154 transfers the heat 130 to the fluid 122. Thus, cooling of the at least one TEG 110 is achieved using the secondary cooling loop 150 in which the fluid 122 receives the heat 130 from the cold-side heat exchanger 112 of the at least one TEG 110 via the cold-side working fluid 154 removing heat 130 from the at least one TEG 110 and transferring it to the fluid 122 in the container 120 (e.g., flowing through the pipeline 124). Heating of the fluid 122 in the container 120 is then achieved indirectly with the fluid 122 in the container 120 (e.g., transported in the pipeline 124) not flowing through the at least one TEG 110. While FIGS. 4A and 4B show that the burner 140 is utilizing a portion of the fluid 122 to produce the heat 142 transmitted to the hot-side heat exchanger 114 (e.g., in a manner similar to that described above with regard to FIGS. 3A and 3B), certain other embodiments utilize a separate fuel source for the burner 140 (e.g., in a manner similar to that described above with regard to FIGS. 3C and 3D).

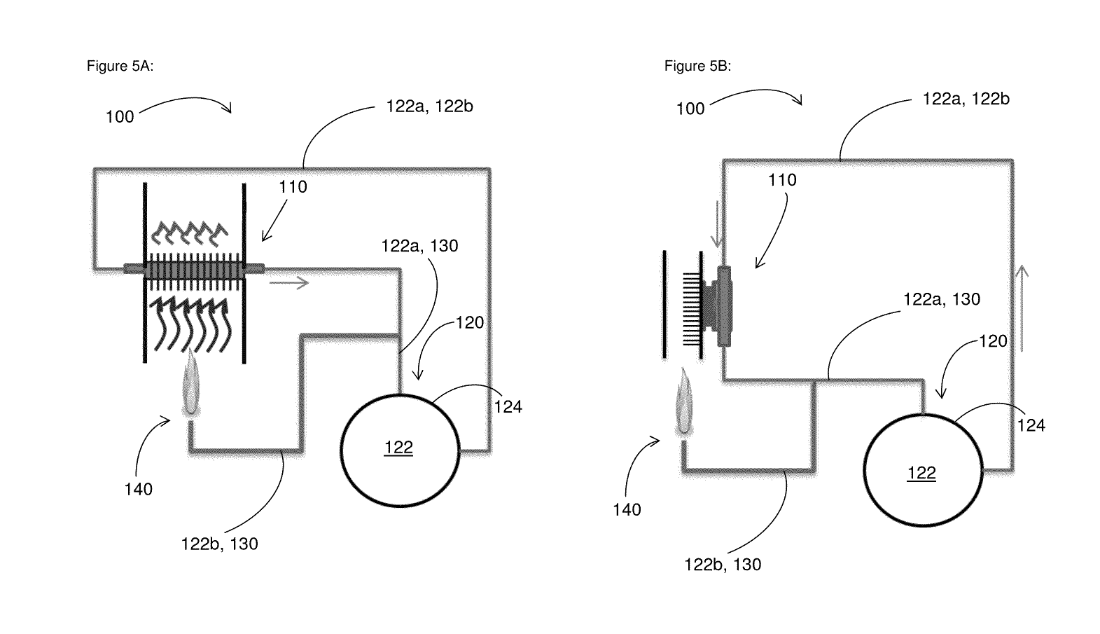

FIGS. 5A and 5B schematically illustrate example TE systems 100 transferring heat 130 to the fluid 122 within the container 120 and utilizing preheating of a portion of the fluid 122 from the container 120 prior to being combusted by the burner 140 in accordance with certain embodiments described herein. The at least one TEG 110 of FIG. 5A comprises at least one TE cartridge (e.g., as described above with regard to FIGS. 3A and 3C) and the at least one TEG 110 of FIG. 5B comprises a planar TEG (e.g., as described above with regard to FIGS. 3B and 3D). In certain such embodiments, a first portion 122a of the fluid 122 in the container 120 (e.g., flowing through the pipeline 124) is directed to flow from the container 120 through the cold-side heat exchanger 112, and back to the container 120. The first portion 112a of the fluid 122 receives heat 130 from the at least one TEG 110 (e.g., waste heat that is not converted into electricity) and the first portion 122a of the fluid 122 carries this heat 130 into the container 120, where it mixes with the fluid 122 in the container 120 (e.g., the main stream of the fluid 122 flowing through the pipeline 124). In this way, the cold-side heat exchanger 112 of the at least one TEG 110 is configured to transfer heat 130 to the fluid 122. A second portion 122b of the fluid 122 in the container 120 (e.g., flowing through the pipeline 124) is directed to flow from the container 120 to the burner 140 where it is combusted (e.g., as described above with regard to FIGS. 3A and 3B). The second portion 122b of the fluid 122 flows through the cold-side heat exchanger 112 along with the first portion 122a of the fluid 122 and is split off from the first portion 122a after having flowed through the cold-side heat exchanger 112. In this way, the second portion 122b of the fluid 122 receives heat 130 from the at least one TEG 110 (e.g., waste heat that is not converted into electricity) and is therefore preheated prior to being combusted by the burner 140. Certain such embodiments can improve combustion efficiency, can reduce the amount of the fluid 122 used in combustion by the burner 140, and/or can reduce greenhouse gas emissions.

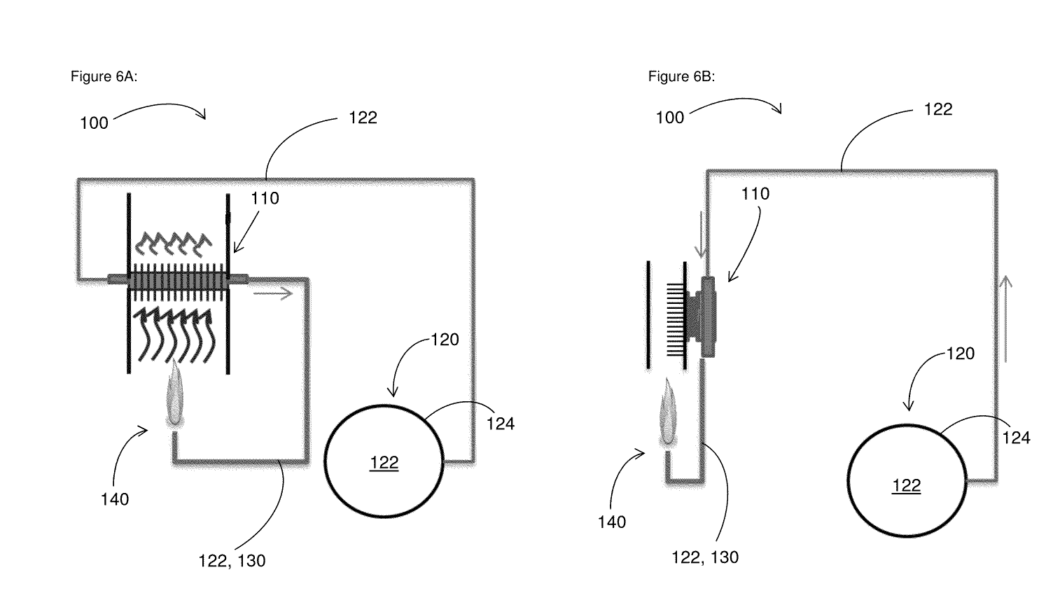

FIGS. 6A and 6B schematically illustrate example TE systems 100 utilizing preheating of fluid 122 from the container 120 prior to being combusted by the burner 140 in accordance with certain embodiments described herein. The at least one TEG 110 of FIG. 6A comprises at least one TE cartridge (e.g., as described above with regard to FIGS. 3A and 3C) and the at least one TEG 110 of FIG. 6B comprises a planar TEG (e.g., as described above with regard to FIGS. 3B and 3D). In certain such embodiments, a portion of the fluid 122 in the container 120 (e.g., flowing through the pipeline 124) is directed to flow from the container 120, through the cold-side heat exchanger 112, to the burner 140 where it is combusted. In this way, the at least one cold-side heat exchanger 112 is configured to transfer heat 130 to the portion of the fluid 122 (e.g., waste heat that is not converted into electricity) and the portion of the fluid 122 is therefore preheated prior to being combusted by the burner 140. Certain such embodiments can improve combustion efficiency, can reduce the amount of the fluid 122 used in combustion by the burner 140, and/or can reduce greenhouse gas emissions. The thermoelectric systems 100 of FIGS. 6A and 6B can be used, for example, in instances where the portion of the fluid 122 flowing through the cold-side heat exchanger 112 is sufficient to cool the at least one TEG 110, or in instances in which the fluid 122 in the main stream remaining in the pipeline 120 is not to be heated.

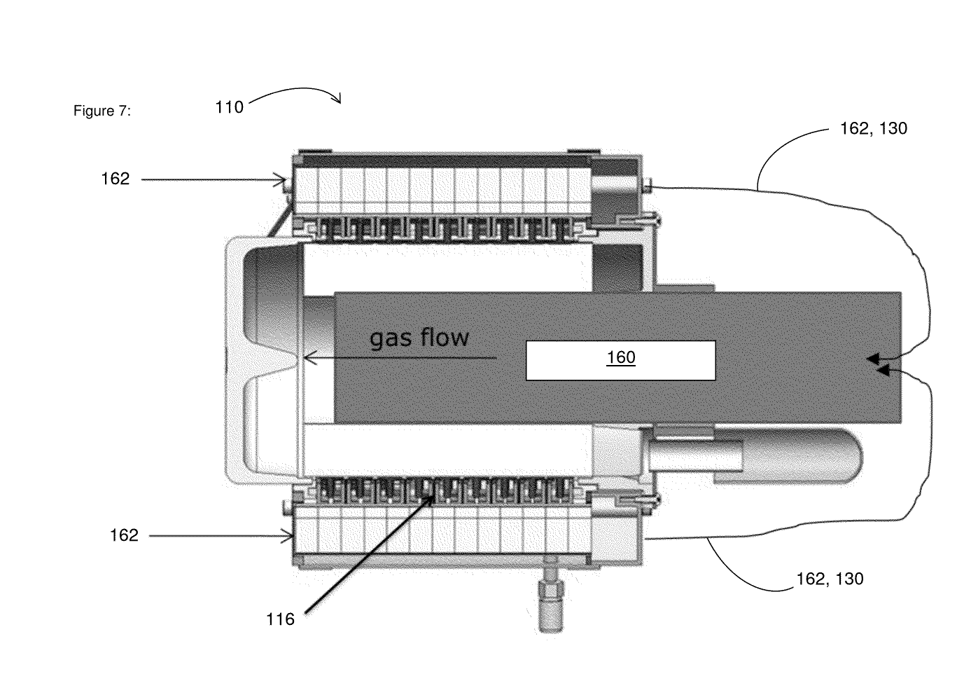

FIG. 7 schematically illustrates an example thermoelectric system 100 comprising a TEG 110 and a combustor 160 that can be used as a burner 140 in accordance with certain embodiments described herein. A cold-side working fluid 162 can comprise at least one of air or fuel (e.g., fluid 122 from the container 120) which flows through the cold-side heat exchanger 112. The cold-side working fluid 162 is preheated prior to flowing into the combustor 160 which ignites the fuel. For example, the cold-side working fluid 162 flowing into the combustor 160 can comprise fuel that is preheated, air that is preheated, or both fuel and air that are preheated. The resulting hot gas outputted from the combustor 160 can be used as a hot-side working fluid 164 that flows through the hot-side heat exchanger 114. The combustor 160 can be a separate unit from the TEG 110 or can be integrated within the TEG 110. In certain embodiments, the efficiency and/or the greenhouse gas emission from the combustion process of the combustor 160 can be improved by preheating the air and/or fuel prior to combustion.

In certain embodiments, the combustor 160 can provide advantages (e.g., lighter weight, less pressure drop, less parasitic power) as compared to conventional recuperators which can recover exhaust heat from the outlet from a TEG. Certain embodiments described herein can avoid the use of a stand-alone recuperator, thereby improving the system-level power density and efficiency by reducing the mass and parasitic power due to an additional pressure drop through the recuperator. In certain such embodiments, the combustor 160 can still benefit from preheated air and/or fuel for improved combustion efficiency. An integrated recuperator 160, as used in certain embodiments described herein, can provide preheating of the air and/or fuel without additional weight or pressure drop.

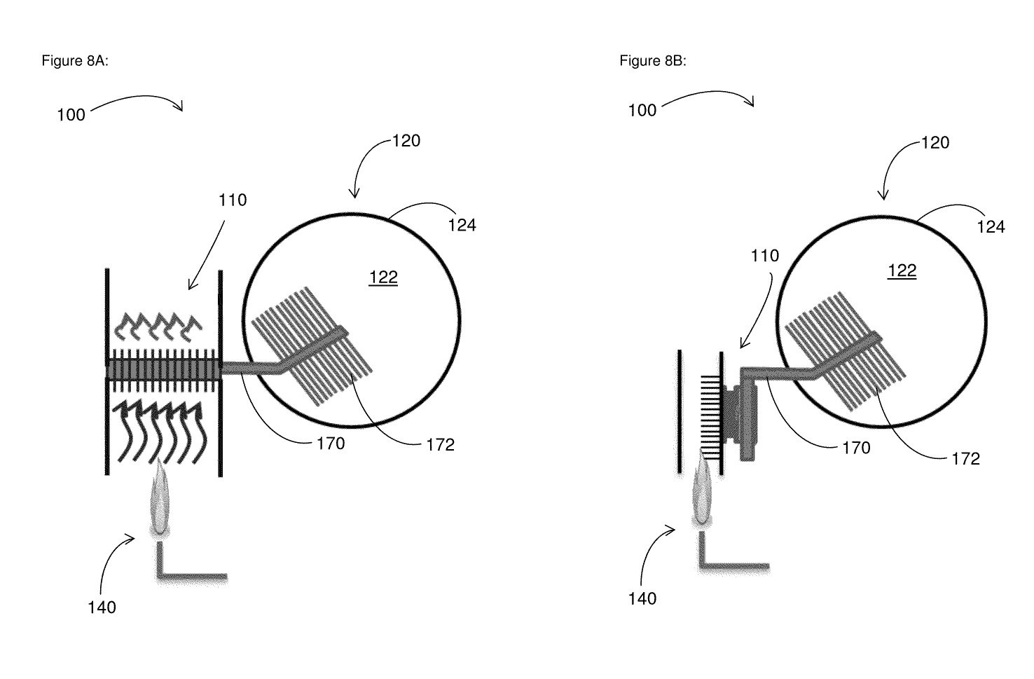

FIGS. 8A and 8B schematically illustrate example thermoelectric systems 100 that are configured to transfer heat 130 from the cold-side heat exchanger 112 of the at least one TEG 110 without having fluid 122 from the container 120 flow through the cold-side heat exchanger 112 in accordance with certain embodiments described herein. The at least one TEG 110 of FIG. 8A comprises at least one TE cartridge (e.g., as described above with regard to FIGS. 3A and 3C) and the at least one TEG 110 of FIG. 8B comprises a planar TEG (e.g., as described above with regard to FIGS. 3B and 3D). The burner 140 burns fuel (e.g., a portion of the fluid 122 from the container 120, or a separate fuel source such as flue-gas or a separate fuel reservoir) to provide heat 150 to the hot-side heat exchanger 114.

The cold-side heat exchanger 112 of FIGS. 8A and 8B comprises at least one energy transmission element 170 (e.g., at least one heat pipe or thermosyphon) that extends from the at least one TEG 110 to the container 120 and is in thermal communication with the fluid 122 (e.g., extending through a wall of the container 120 to be in thermal communication with the fluid 122 in the container 120). In certain embodiments, the at least one energy transmission element 170 can utilize gravity or can otherwise be orientation-dependent. In certain embodiments, the at least one energy transmission element 170 does not comprise any moving parts (except the material moving between the first and second positions), and can be characterized as providing passive energy transfer or heat exchange. Examples of TEGs 110 and energy transmission elements 170 compatible with certain embodiments described herein are described in U.S. Provisional Appl. No. 61/664,621, filed Jun. 26, 2012 and incorporated in its entirety by reference herein.

The cold-side heat exchanger 112 of the at least one TEG 110 is configured to transfer the heat 130 (e.g., waste heat that is not converted into electricity) to the container 120 (e.g., pipeline 124). For example, in certain embodiments, as shown in FIGS. 8A and 8B, the cold-side heat exchanger 112 comprises a plurality of fins 172 that are within the container 120 (e.g., pipeline 124) and in thermal communication with the at least one energy transmission element 170 and in thermal communication with the fluid 122 in the container 120 (e.g., flowing through the pipeline 124). In certain other embodiments, the at least one energy transmission element 170 can be in thermal communication with a heater jacket that is in thermal communication with the container 120 (e.g., around the pipeline 124). The fluid 122 in the container 120 and the at least one energy transmission element 170 would then not be in direct contact with one another. In certain embodiments, use of the at least one energy transmission element 170 advantageously avoids pumping of a cold-side working fluid through the cold-side heat exchanger 112, and can therefore increase system-level efficiency.

Existing TEG systems are currently used with pipelines to generate small amounts of power for process control, cathodic protection, etc. However, in conventional systems, the heat is generated on-site using external fuel and the heat that is not converted in electricity is wasted and released to the atmosphere. This waste heat can be more than 90% of chemical potential of the fuel used to run the TEG system. Furthermore, conventional systems heat the fluid at the pump station, independent of any TEG systems being used along the pipeline. In contrast, certain embodiments described herein used in conjunction with a pipeline 124 can use the waste heat 130 to improve the overall efficiency of the pipeline 124 by heating the fluid 122 (e.g., combustible fluid, petroleum) being pumped through the pipeline 124. Certain embodiments described herein can advantageously use the TEG system 100 as a pipeline heater to reduce fuel expenses in heating up the pipeline 124 using the same fuel (e.g., fluid 122) as is used to generate electricity with the TEG system 100. Certain embodiments described herein can also advantageously distribute heating along the pipeline 124 (e.g., by using multiple TEG systems 100 along the pipeline 124) and by doing so, advantageously maintain elevated temperatures of the fluid 122 (e.g., combustible fluid, petroleum, crude oil) and reduce the fluid viscosity along the pipeline 124. Maintaining lower fluid viscosity can be important in controlling pressure drop (hence reducing pumping power) since pressure drop is proportional to fluid viscosity.

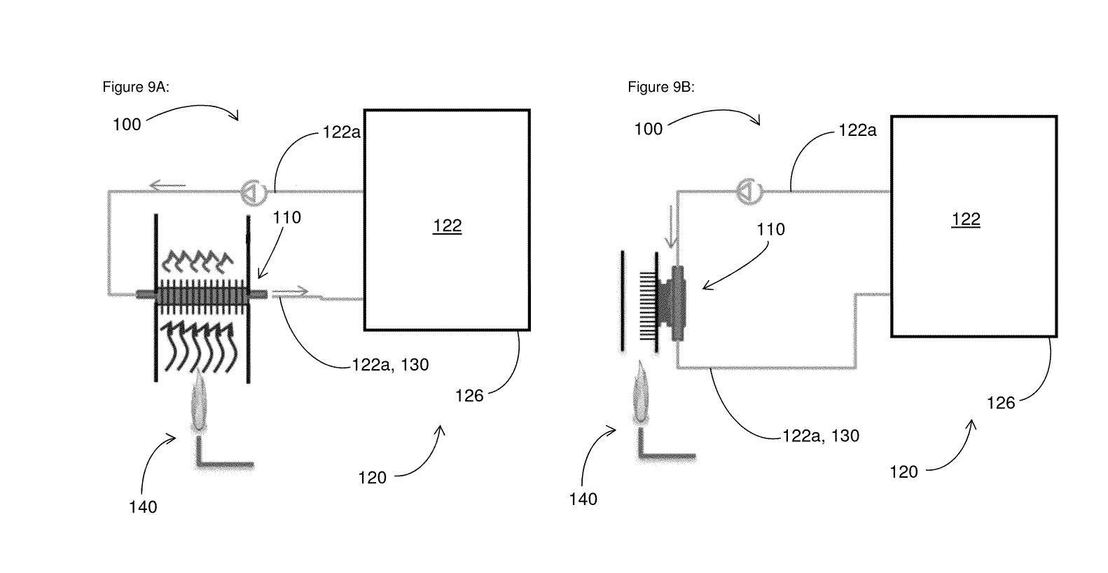

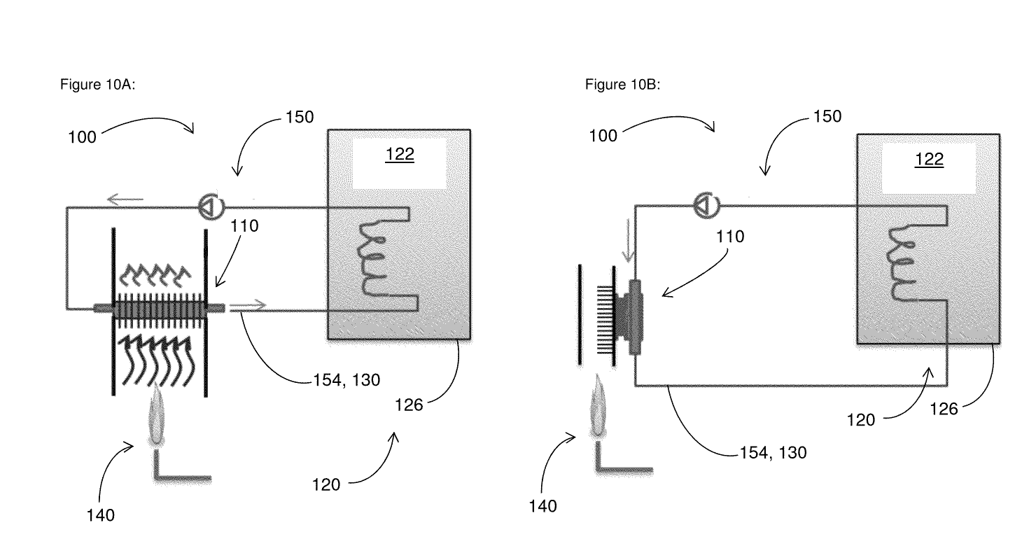

FIGS. 9A and 9B schematically illustrate example thermoelectric systems 100 in which fluid 122 (e.g., combustible fluid, petroleum, gas, oil) from a reservoir 126 is directly circulated through the at least one TEG 110 in accordance with certain embodiments described herein. A burner 140 creates a flame which heats air or other fluid that then flows in thermal communication with the hot-side heat exchanger 114. A first portion 122a of the fluid 122 from the container 120 (e.g., the reservoir 126) is directed to flow from the container 120 through the cold-side heat exchanger 112, and back to the container 120. The first portion 112a of the fluid 122 receives heat 130 from the at least one TEG 110 (e.g., waste heat that is not converted into electricity) and the first portion 122a of the fluid 122 carries the heat 130 into the container 120, where it mixes with the fluid 122 within the container 120 (e.g., within the reservoir 126). In this way, the cold-side heat exchanger 112 of the at least one TEG 110 is configured to transfer heat 130 to the fluid 122. In certain embodiments, the fuel combusted by the burner 140 can comprise a second portion 122b of the fluid 122 in the container 120 (e.g., the reservoir 126) (e.g., in a manner similar to that discussed above with regard to FIGS. 3A and 3B). In certain other embodiments, a separate fuel source can be utilized for operating the burner 140 (e.g., in a manner similar to that discussed above with regard to FIGS. 3C and 3D). Examples of the separate fuel source can include, but are not limited to, a natural gas source and a flue-gas source.

FIGS. 10A and 10B schematically illustrate example TE systems 100 utilizing a secondary cooling loop 150 in accordance with certain embodiments described herein. The at least one TEG 110 of FIG. 10A comprises at least one TE cartridge (e.g., as described above with regard to FIGS. 3A and 3C) and the at least one TEG 110 of FIG. 10B comprises a planar TEG (e.g., as described above with regard to FIGS. 3B and 3D). In FIGS. 10A and 10B, the container 120 (e.g., reservoir 126) comprises a coolant loop 150 in thermal communication with the fluid 122 in the container 120 (e.g., the reservoir 126). A cold-side working fluid 154 is pumped through the coolant loop 150 (e.g., via pump 156) to the cold-side heat exchanger 112, where the cold-side working fluid 154 picks up heat 130 from the cold-side heat exchanger 112 (e.g., waste heat) and flows back through the cooling loop 150 towards the reservoir 126 where the cold-side working fluid 154 transfers the heat 130 to the fluid 122. Thus, cooling of the at least one TEG 110 is achieved using the secondary cooling loop 150 in which the fluid 122 receives the heat 130 from the cold-side heat exchanger 112 of the at least one TEG 110 via the cold-side working fluid 154 removing heat 130 from the at least one TEG 110 and transferring it to the fluid 122 in the container 120 (e.g., the reservoir 126). Heating of the fluid 122 in the container 120 is then achieved indirectly with the fluid 122 in the container 120 (e.g., the reservoir 126) not flowing through the at least one TEG 110. In certain embodiments, the burner 140 can utilize a portion of the fluid 122 as fuel to be combusted to produce the heat 142 transmitted to the hot-side heat exchanger 114 (e.g., in a manner similar to that described above with regard to FIGS. 3A and 3B). In certain other embodiments, a separate fuel source is utilized for the burner 140 (e.g., in a manner similar to that described above with regard to FIGS. 3C and 3D).

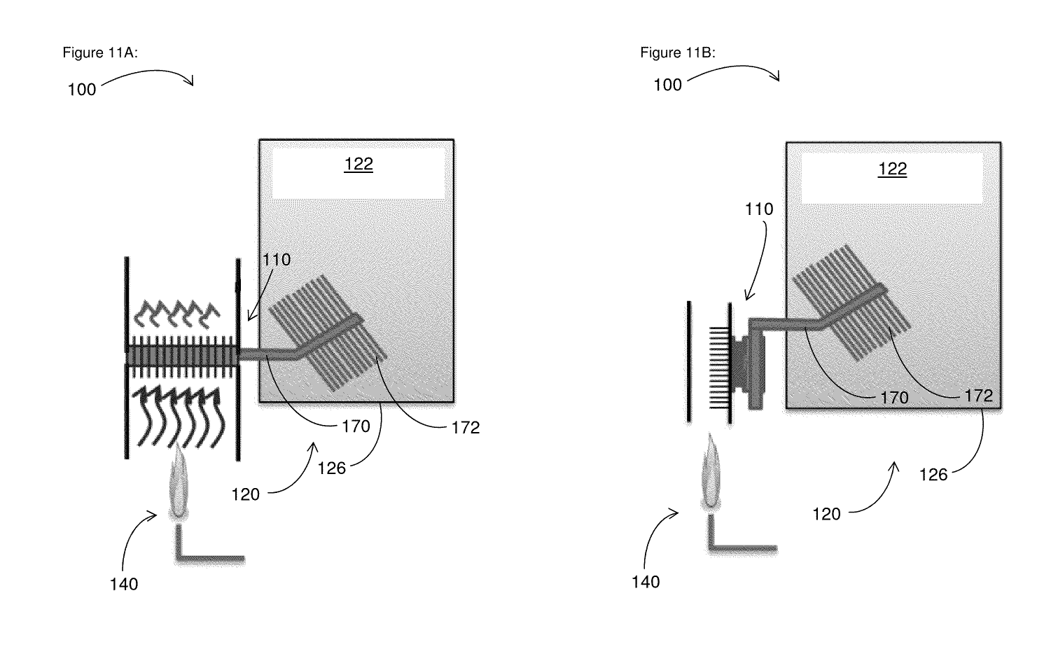

FIGS. 11A and 11B schematically illustrate example thermoelectric systems 100 that are configured to transfer heat 130 from the cold-side heat exchanger 112 of the at least one TEG 110 without having fluid 122 from the container 120 (e.g., reservoir 126) flow through the cold-side heat exchanger 112 in accordance with certain embodiments described herein. The at least one TEG 110 of FIG. 11A comprises at least one TE cartridge (e.g., as described above with regard to FIGS. 3A and 3C) and the at least one TEG 110 of FIG. 11B comprises a planar TEG (e.g., as described above with regard to FIGS. 3B and 3D). The burner 140 burns fuel (e.g., a portion of the fluid 122 from the container 120, or a separate fuel source such as flue-gas or a separate fuel reservoir) to provide heat 142 to the hot-side heat exchanger 114.

The cold-side heat exchanger 112 of FIGS. 11A and 11B comprises at least one energy transmission element 170 (e.g., at least one heat pipe or thermosyphon) that extends from the at least one TEG 110 to the container 120 (e.g., reservoir 126) and is in thermal communication with the fluid 122 (e.g., extending through a wall of the reservoir 126 to be in thermal communication with the fluid 122 in the reservoir 126). In certain embodiments, the at least one energy transmission element 170 can utilize gravity or can otherwise be orientation-dependent. In certain embodiments, the at least one energy transmission element 170 does not comprise any moving parts (except the material moving between the first and second positions), and can be characterized as providing passive energy transfer or heat exchange. Examples of TEGs 110 and energy transmission elements 170 compatible with certain embodiments described herein are described in U.S. Provisional Appl. No. 61/664,621, filed Jun. 26, 2012 and incorporated in its entirety by reference herein.

The cold-side heat exchanger 112 of the at least one TEG 110 is configured to transfer the heat 130 (e.g., waste heat that is not converted into electricity) to the container 120 (e.g., reservoir 126). For example, in certain embodiments, as shown in FIGS. 11A and 11B, the cold-side heat exchanger 112 comprises a plurality of fins 172 that are within the container 120 (e.g., reservoir 126) and in thermal communication with the at least one energy transmission element 170 and in thermal communication with the fluid 122 in the container 120 (e.g., reservoir 126). In certain other embodiments, the at least one energy transmission element 170 can be in thermal communication with a heater jacket that is in thermal communication with the container 120 (e.g., reservoir 126). The fluid 122 in the container 120 and the at least one energy transmission element 170 would then not be in direct contact with one another. In certain embodiments, use of the at least one energy transmission element 170 advantageously avoids pumping of a cold-side working fluid through the cold-side heat exchanger 112, and can therefore increase system-level efficiency.

In certain embodiments, the fluid 122 in the container 120 (e.g., reservoir 126) can comprise water. For example, the thermoelectric system 100 of at least one of FIGS. 9A, 9B, 10A, 10B, 11A, and 11B can comprise a tank or reservoir 126 containing the water which can be heated up using the waste heat 130 from the at least one TEG 110. The size of the reservoir 126 can be determined by the particular application (e.g., 1 to 300 gallons for a home water heater). Larger size reservoirs 126 can be used in industrial applications to heat water or other process fluids. In certain embodiments, heating of the process fluids can be used to improve separation of gases and liquids or to improve separation of liquids with different densities.

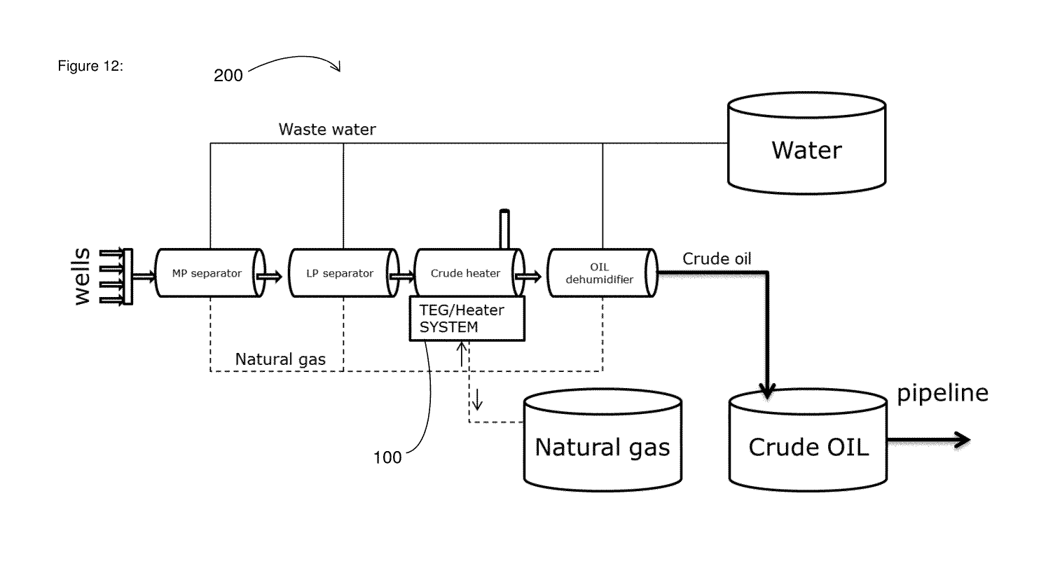

In certain embodiments, the fluid 122 in the container 120 (e.g., reservoir 126) can comprise crude oil. For example, the thermoelectric system 100 of at least one of FIGS. 9A, 9B, 10A, 10B, 11A, and 11B can be integrated at an oil well or in the early stages of processing crude oil. In certain embodiments, the waste heat from the at least one TEG 110 can be used to heat the crude oil for various purposes (e.g., to decrease its viscosity to facilitate transportation through a pipeline, or for further processing, such as to separate water and natural gas). FIG. 12 schematically illustrates an example processing system 200 for crude oil in accordance with certain embodiments described herein. In the processing system 200, a thermoelectric system 100 comprising at least one TEG 110 is used to generate electricity and the waste heat from the at least one TEG 110 is used to heat the crude oil being processed. In certain such embodiments, waste natural gas from the crude oil can be used as the fuel for the burner 140 providing heat 142 to the hot-side heat exchanger 114.

In certain embodiments, other working fluids can be used to cool the cold-side heat exchanger 112. For example, in applications in which oils are used to lubricate gears, such as in an engine transmission, these oils can be used on the cold side of the at least one TEG 110. Warming these oils can improve the energy efficiency of the transmission system by reducing friction losses. The coupling of the at least one TEG 110 and the transmission fluid can be achieved using the various systems and methods described herein.

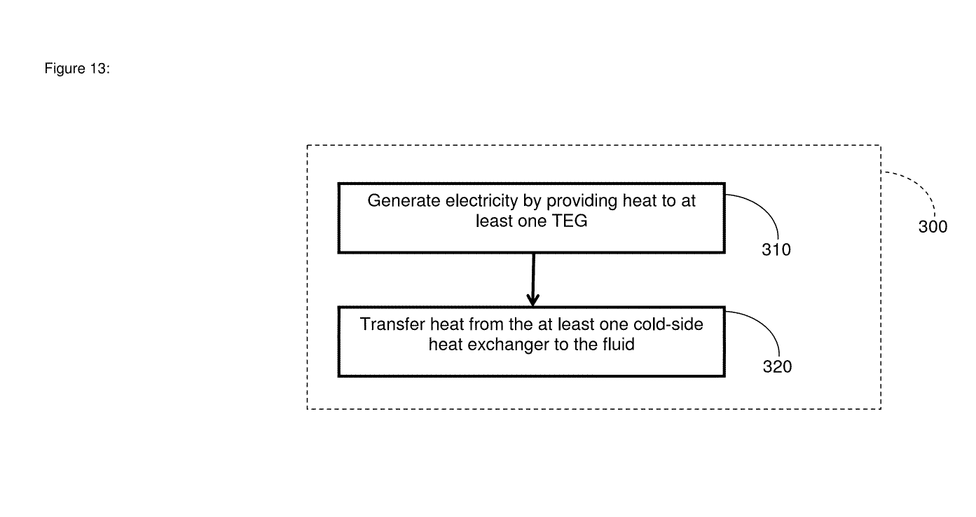

FIG. 13 is a flow diagram of an example method 300 for heating a fluid 122 (e.g., combustible fluid, petroleum, crude oil) in accordance with certain embodiments described herein. In an operational block 310, the method 300 comprises generating electricity by providing heat to at least one TEG 110, examples of which are described herein. In an operational block 320, the method 300 further comprises transferring heat 130 from the at least one cold-side heat exchanger 112 of the at least one TEG 110 to the fluid 122. For example, in certain embodiments, transferring heat from the at least one cold-side heat exchanger 112 to the fluid 122 comprises flowing a portion of the fluid 122 from a container 120 through the cold-side heat exchanger 112 to heat the portion of the fluid 122. The heated portion of the fluid 122 can be returned back to the container 120. In certain other embodiments, transferring heat from the at least one cold-side heat exchanger 112 to the fluid 122 comprises flowing a working fluid through and in thermal communication with the at least one cold-side heat exchanger 112 and using the working fluid to heat the fluid 122. In certain embodiments, the method 300 further comprises flowing the portion of the fluid 122 heated by the cold-side heat exchanger 112 to a burner 140 configured to combust the portion of the fluid 122, and combusting the portion of the fluid 122 to provide heat to the at least one hot-side heat exchanger 114 of the at least one TEG 110.

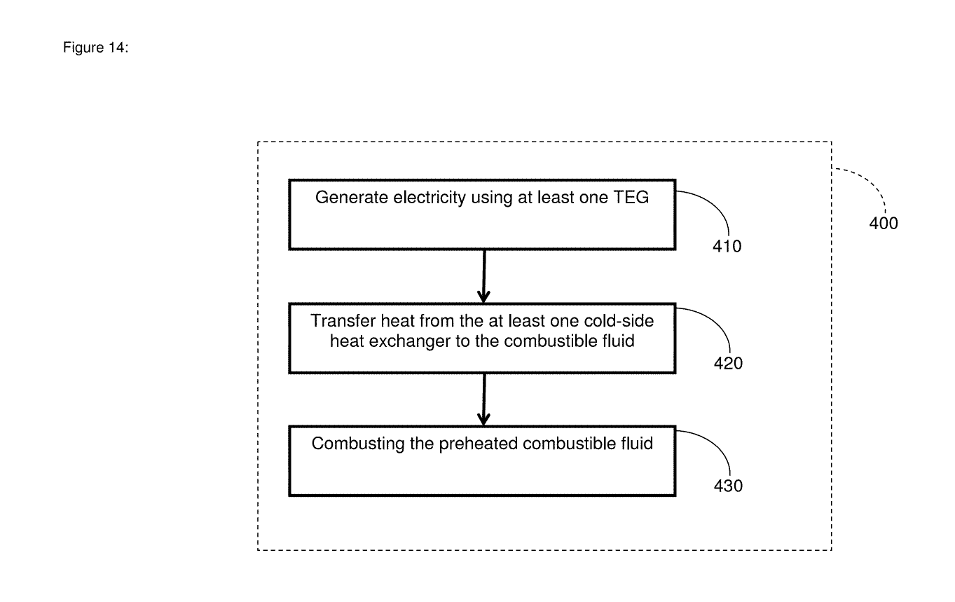

FIG. 14 is a flow diagram of an example method 400 for generating electricity by combusting a combustible fluid 122 in accordance with certain embodiments described herein. In an operational block 410, the method 400 comprises generating electricity using at least one TEG 110, example of which are described herein. In an operational block 420, the method 400 further comprises transferring heat 130 from the at least one cold-side heat exchanger 112 of the at least one TEG 110 to the combustible fluid 122 to preheat the combustible fluid 122. In an operational block 430, the method 400 further comprises combusting the preheated combustible fluid 122 to provide heat 142 to the at least one hot-side heat exchanger 114 of the at least one TEG 110. In certain embodiments, the method 400 further comprises flowing the combustible fluid 122 from a pipeline 124 or a reservoir 126. In certain embodiments, transferring heat 130 from the at least one cold-side heat exchanger 112 to the combustible fluid 122 comprises flowing the combustible fluid 122 through the at least one cold-side heat exchanger 112. In certain other embodiments, transferring heat 130 from the at least one cold-side heat exchanger 112 to the combustible fluid 122 comprises using a secondary coolant loop 150 to transfer the heat 130 from the at least one cold-side heat exchanger 112 to the combustible fluid 122.

In certain embodiments described herein, the fluid 122 in the container 120 (e.g., a pipeline 124 or a reservoir 126) is used as a coolant for the at least one TEG 110. Certain such embodiments can provide an advantage over conventional systems in which cooling of the TEG system is achieved using secondary loops or simply using natural convection and radiation. The container 120 (e.g., pipeline 124 or reservoir 126) can provide the coolant (e.g., cold-side working fluid) that is available on site at no additional cost. Using this fluid 122, instead of ambient air, as a coolant can improve heat transfer efficiency and can therefore reduce the TEG cold side temperature. Since the efficiency of a TEG system is proportional to Carnot efficiency, or in other words to the difference in temperature between the hot side and the cold side, reducing the cold side temperature can increase the TEG efficiency and can increase the electrical power generated by the TEG system.

Certain embodiments described herein can advantageously couple a TEG system with one or more engines that are lubricated by at least one engine lubricant to heat the at least one lubricant (e.g., combustible lubricant, non-combustible lubricant) and to control lubricant temperature. By doing so, certain such embodiments can advantageously minimize friction losses.

Discussion of the various configurations herein has generally followed the configurations schematically illustrated in the figures. However, it is contemplated that the particular features, structures, or characteristics of any configurations discussed herein may be combined in any suitable manner in one or more separate configurations not expressly illustrated or described. In many cases, structures that are described or illustrated as unitary or contiguous can be separated while still performing the function(s) of the unitary structure. In many instances, structures that are described or illustrated as separate can be joined or combined while still performing the function(s) of the separated structures.

Various configurations have been described above. Although the invention has been described with reference to these specific configurations, the descriptions are intended to be illustrative and are not intended to be limiting. Various modifications and applications may occur to those skilled in the art without departing from the true spirit and scope of the invention as defined in the appended claims.

What is claimed is:

1. A thermoelectric system comprising:
at least one thermoelectric generator comprising:
at least one cold-side heat exchanger;
at least one hot-side heat exchanger; and
a plurality of thermoelectric elements in thermal communication with the at least one cold-side heat exchanger and in thermal communication with the at least one hot-side heat exchanger; and
a combustible fluid, wherein the at least one cold-side heat exchanger is configured to transfer heat to the combustible fluid.

2. The system of claim 1, wherein the combustible fluid comprises crude oil.

3. The system of claim 1, wherein the combustible fluid is in a container.

4. The system of claim 3, wherein the container comprises a pipeline having the combustible fluid flowing through the pipeline.

5. The system of claim 3, wherein the container comprises a reservoir holding the combustible fluid.

6. The system of claim 3, wherein a first portion of the combustible fluid flows from the container, flows through the at least one cold-side heat exchanger, receives the heat from the at least one cold-side heat exchanger, and flows back to the container.

7. The system of claim 6, wherein a second portion of the combustible fluid flows from the container, flows through the at least one cold-side heat exchanger, receives the heat from the at least one cold-side heat exchanger, and flows to a burner configured to combust the second portion of the combustible fluid and to provide heat to the at least one hot-side heat exchanger.

8. The system of claim 3, wherein a portion of the combustible fluid flows from the container, flows through the at least one cold-side heat exchanger, receives the heat from the at least one cold-side heat exchanger, and flows to a burner configured to combust the second portion of the combustible fluid and to provide heat to the at least one hot-side heat exchanger.

9. The system of claim 1, wherein the system further comprises a secondary coolant loop in thermal communication with the at least one cold-side heat exchanger and in thermal communication with the combustible fluid.

10. The system of claim 1, wherein the cold-side heat exchanger comprises at least one energy transmission element in thermal communication with the combustible fluid.

11. A system comprising:
an engine; and
at least one thermoelectric generator comprising:
at least one cold-side heat exchanger;
at least one hot-side heat exchanger; and
a plurality of thermoelectric elements in thermal communication with the at least one cold-side heat exchanger and in thermal communication with the at least one hot-side heat exchanger; and
an engine lubricant, wherein the at least one cold-side heat exchanger is configured to transfer heat to the engine lubricant.

12. A method of heating a combustible fluid, the method comprising:
generating electricity by providing heat to at least one thermoelectric generator comprising:
at least one cold-side heat exchanger;
at least one hot-side heat exchanger; and
a plurality of thermoelectric elements in thermal communication with the at least one cold-side heat exchanger and in thermal communication with the at least one hot-side heat exchanger; and
transferring heat from the at least one cold-side heat exchanger to the combustible fluid.

13. The method of claim 12, wherein the combustible fluid comprises crude oil.

14. The method of claim 12, wherein transferring heat from the at least one cold-side heat exchanger to the combustible fluid comprises flowing a portion of the combustible fluid from a container through the cold-side heat exchanger to heat the portion of the combustible fluid.

15. The method of claim 14, further comprising flowing the portion of the combustible fluid heated by the cold-side heat exchanger back to the container.

16. The method of claim 14, wherein the method further comprises:
flowing the portion of the combustible fluid heated by the cold-side heat exchanger to a burner configured to combust the portion of the combustible fluid; and
combusting the portion of the combustible fluid to provide heat to the at least one hot-side heat exchanger.

17. The method of claim 12, wherein transmitting heat from the at least one cold-side heat exchanger to the combustible fluid comprises flowing a working fluid through and in thermal communication with the at least one cold-side heat exchanger and using the working fluid to heat the combustible fluid.

18. The method of claim 12, wherein the cold-side heat exchanger comprises at least one energy transmission element, and transmitting heat from the at least one cold-side heat exchanger to the combustible fluid comprises flowing the combustible fluid in thermal communication with the at least one energy transmission element.

19. A method of heating an engine lubricant, the method comprising:
generating electricity by providing heat to at least one thermoelectric generator comprising:
at least one cold-side heat exchanger;
at least one hot-side heat exchanger; and
a plurality of thermoelectric elements in thermal communication with the at least one cold-side heat exchanger and in thermal communication with the at least one hot-side heat exchanger; and
transferring heat from the at least one cold-side heat exchanger to an engine lubricant.

20. A thermoelectric system comprising:
at least one thermoelectric generator comprising:
at least one cold-side heat exchanger;
at least one hot-side heat exchanger; and
a plurality of thermoelectric elements in thermal communication with the at least one cold-side heat exchanger and in thermal communication with the at least one hot-side heat exchanger;
a combustible fluid, wherein the at least one cold-side heat exchanger is configured to transfer heat to a portion of the combustible fluid; and
a burner configured to combust the portion of the combustible fluid and to provide heat to the at least one hot-side heat exchanger.

21. The system of claim 20, wherein the portion of the combustible fluid flows from a pipeline or a reservoir.

22. The system of claim 21, wherein the portion of the combustible fluid flows through the at least one cold-side heat exchanger, receives the heat from the at least one cold-side heat exchanger, and flows to the burner.

23. The system of claim 20, wherein the system further comprises a secondary coolant loop in thermal communication with the at least one cold-side heat exchanger and in thermal communication with the portion of the combustible fluid.

24. A method of generating electricity by combusting a combustible fluid, the method comprising:
generating electricity using at least one thermoelectric generator comprising:
at least one cold-side heat exchanger;
at least one hot-side heat exchanger; and
a plurality of thermoelectric elements in thermal communication with the at least one cold-side heat exchanger and in thermal communication with the at least one hot-side heat exchanger;
transferring heat from the at least one cold-side heat exchanger to the combustible fluid to preheat the combustible fluid; and
combusting the preheated combustible fluid to provide heat to the at least one hot-side heat exchanger.

25. The method of claim 24, further comprising flowing the combustible fluid from a pipeline or a reservoir.

26. The method of claim 24, wherein transferring heat from the at least one cold-side heat exchanger to the combustible fluid comprises flowing the combustible fluid through the at least one cold-side heat exchanger.

27. The method of claim 24, wherein transferring heat from the at least one cold-side heat exchanger to the combustible fluid comprises using a secondary coolant loop to transfer heat from the at least one cold-side heat exchanger to the combustible fluid.
